(19) United States
(12) Patent Application Publication
(10) Pub. No.: US 2026/0324449 A1
(43) Pub. Date: Oct. 15, 2026

(54) METHODS AND SYSTEMS OF MANUFACTURING SUBSTRATES HAVING MICRO-HOLES

(71) Applicant: UNITED BENEFIT CORP., New Taipei City (TW)

(72) Inventor: Shih-Chang CHANG, New Taipei City (TW)

(21) Appl. No.: 19/638,219

(22) Filed: Apr. 3, 2026

Related U.S. Application Data
(60) Provisional application No. 63/788,140, filed on Apr. 14, 2025.

(51) Int. Cl. H10W 70/05; C23C 18/16

(52) U.S. Cl. CPC H10W 70/095; C23C 18/1603; C23C 18/1628; C23C 18/1648

(57) ABSTRACT

Disclosed is a method and a system of manufacturing a substrate having micro-holes, the system includes a solution storage tank, a processing chamber, a boost pump and a recycle pump, wherein the solution storage tank is configured to be filled with a processing solution; the processing chamber has a substrate placement area, a pressure increasing area and a pressure reducing area, a substrate having micro-holes can be horizontally placed and fixed in the substrate placement area, the pressure increasing area is located below the substrate placement area, the pressure reducing area is located above the substrate placement area; the boost pump is connected to the solution storage tank and the pressure increasing area via pipelines; and the recycle pump is connected to the solution storage tank and the pressure reducing area via pipelines.

### CROSS-REFERENCE TO RELATED APPLICATIONS

The present application is a nonprovisional application claiming benefit from a prior-filed provisional application bearing a Ser. No. 63/788,140 and filed Apr. 14, 2025, the entity of which is incorporated herein for reference.

### BACKGROUND OF THE INVENTION

### 1. Field of the Invention

The present application relates to a method and a system of manufacturing a substrate, and more particularly to a method and a system of manufacturing a substrate having micro-holes.

### 2. The Prior Arts

The development of AI technology has further increased the demand for accelerated computing, and the requirement for chip density in servers also has risen accordingly. The packaging process must integrate different types of chips, including logic chips, memory chips, and RF chips, by stacking them together to improve chip performance, reduce size, and reduce power consumption. Due to the physical limitations of materials, advanced 3D packaging requires the use of an interposer that needs forming redistribution layers (RDL) on the upper and lower surfaces of a substrate of tens of square centimeters and tens thousands or even hundred thousand of vertical conductive lines connecting to the redistribution layers, and different functional chip assemblies are then packaged with the interposer. Using conventional plastic substrates as the packaging substrates has problems such as power consumption, expansion, and warping. Some companies have started to use glass substrates to develop substrates for 3D packaging. Existing technologies of forming vertical conductive lines in glass substrates mainly include the following processes: forming through-holes (also known as through vias); metallizing the through-holes.

A method of forming through glass vias (TGV) in glass substrates mainly uses a short-pulse laser beam to focus on the glass substrate to form an initial via in the area irradiated by the laser beam, and structures around the initial via are modified or destroyed that makes the structures easier to be etched than area not irradiated by the laser beam. Because the vias formed in the glass substrates for 3D packaging must be high aspect ratios (the ratio of glass substrate thickness to via diameter), it is difficult to uniformly etch the central region of the initial via, glass fragments produced by the etching can easily remain inside the vias, resulting in poor via morphology (e.g., non-circular) and excessively rough inner wall.

The US patent (publication NO. US2015060402A1) discloses a method for forming vias in glass substrates, the methods includes laser drilling the via through at least a portion of a thickness of the glass substrate from an incident surface of the glass substrate. The method further includes etching the glass substrate for an etching duration to increase a diameter of an incident opening of the via and applying ultrasonic energy to the glass substrate during at least a portion of the etching duration. The applied ultrasonic energy has a frequency between 40 kHz and 192 kHz. The laser source 110 is a solid state ultraviolet laser (such as a Nd:YAG laser) emitting a pulsed laser beam 112 having a wavelength of 355 nm, and the laser sources with other wavelengths may be used. The glass substrate may be positioned on a translating table such that it may be translated in two (or three) dimensions to drill multiple pilot holes in the glass substrate. The pilot hole is laser drilled from an incident surface of the glass substrate, through the thickness of the glass substrate, to an exit surface of the glass substrate. A diameter of the incident opening is typically larger than the diameter of the exit opening. The etching apparatus includes an outer container, a water tank, an etching solution tank, a sample holder, ultrasonic transducers, and an ultrasonic generator, the etching solution tank is disposed within the water tank and the water tank is disposed within the outer container. The ultrasonic transducers may be disposed within the outer container and interface with the water tank, such that ultrasonic energy may be imparted to water contained within the water tank, which is then imparted to the etching solution contained within the etching solution tank and ultimately imparted to the glass substrate supported by the sample holder in the etching solution tank. The water tank includes water filled to a level sufficient to ensure that ultrasonic energy produced by the ultrasonic transducers is transferred to the glass substrate immersed within the etching solution tank. The etching solution is an aqueous solution including deionized water, a primary acid, and a secondary acid. The primary acid may be hydrofluoric acid, and the secondary acid may be nitric acid, hydrochloric acid, or sulfuric acid. In some embodiments, the etching solution may include a primary acid other than hydrofluoric acid and/or a secondary acid other than nitric acid, hydrochloric acid, or sulfuric acid. Ultrasonic energy is applied by the ultrasonic transducers while the glass substrate is being etched. The glass substrate is etched with the etching solution for an etching duration to increase a diameter of the through via, the glass substrate is mechanically agitated, such as by moving the glass substrate up and down or side to side in the etching solution either manually or by machine, during at least a portion of the etching duration to facilitate removal of sludge from the via.

After the through-holes are formed in the glass substrate, the glass surface is cleaned by using ultraviolet (UV) light irradiation and alkaline degreasing containing a bonding agent, which improves the adhesion of copper to the glass. Then, titanium with thicknesses of 300 nm and copper with thicknesses of 500 nm, are respectively deposited on the entire surface of the glass (including the front, back, and TGV sidewalls) by using physical vapor deposition (PVD) to form the seed layer necessary for the subsequent copper filling process; and copper is filled into the through-holes by using electrochemical deposition to complete the process of metallizing through-holes. However, due to the high aspect ratio of the vias in the glass substrate, defects can easily occur in the seed layer of physical vapor deposition, and the defects lead to even greater defects in subsequent copper filling operations. Therefore, the industry continues to actively develop the wet electroless plating, which uses the full coverage of reactive solutions to displace obstacles caused by poor morphology and roughness of the vias, so as to ensure that the seed layer is completely covered in the vias and remains continuous.

PCT patent (publication No. WO2024217394A1) discloses a method for metallizing through-glass vias in a glass substrate includes cleaning and modifying a surface of the glass substrate; applying an electroless plating solution comprising a copper ion to deposit a copper seed layer on the surface of the glass and on the sidewall of the plurality of vias; disposing an electrolyte within the plurality of vias; positioning an electrode within the electrolyte and applying a first direct current under potential control mode for a first period between the electrode and the glass substrate so as to reduce the copper ions into copper to form a bridge attached on a sidewall and at the central part of each of the plurality of vias; applying a second direct current under current control mode for a second period between the electrode and the glass substrate to fill the vias such that each of the plurality of vias is filled with copper. The thickness of the glass substrate is greater than or equal to 50 μm and less than or equal to 1200 μm, and the plurality of vias has an average diameter of greater than or equal to 8 μm and less than or equal to 30 μm. The glass substrate may be cleaned by a process such as O2 plasma, UV-ozone, or RCA cleaning to remove organics and other impurities (metals, for example) that would interfere with the silane reacting with the surface silanol groups. Washes based on other chemistries may also be used, for example, HF or H2SO4 wash chemistries, the cleaned glass substrate has a water contact angle of less than or equal to 7 degrees. The electroless plating is used to deposit a seed layer 300 of a conductive material (e.g., a copper seed layer) on the surface of the glass substrate, enabling an electroplating technique to be used to fill the vias with electrically conductive material. Commercially available kits and/or electroless plating solutions may be employed to deposit the seed layer. The glass substrate is wetted by submerging the glass substrate including the seed layer in deionized water to ensure that each of the vias is wetted, and an ultrasonic energy may be applied to the glass substrate while the glass substrate is submerged in the water to enhance wetting and bubble removal. The glass substrate may be submerged in an electrolyte solution such that the electrolyte enters the vias. The electrolyte includes ions of the electrically conductive material, for example, copper ions, to be deposited on the seed layer. The glass substrate including the seed layer is the working electrode, or cathode, and the other two electrodes are anodes. In such embodiments, the anodes may be positioned on opposite sides of the glass substrate such that plating of the electrically conductive material may be conducted symmetrically from both sides of the glass substrate. A first direct current is applied under potential control mode in a first electrolyte for a first period between the electrode and the glass substrate, so as to reduce the copper ions into copper to form a bridge attached on a sidewall and at the central part of each of the plurality of vias, a thickness of a center of the bridge is greater than or equal to half of the average diameter of the plurality of vias. A second direct current is applied under current control mode in a second electrolyte for a second period between the electrode and the glass substrate, the plurality of vias is filled with copper, the electrolyte is an electrolyte bath consisting of CuSO4, H2SO4, chloride ions, and NTB.

FIG. 1 illustrates a top view of a poorly formed through-hole and an electron micrograph of a conventional glass substrate in a vertical cross-section. As shown in FIG. 1, glass is a non-crystalline material (close to a non-flowing liquid), during the process of forming seed holes 10 (i.e. initial through-holes) in a conventional glass substrate 1 by irradiating it with a laser beam, the morphology of the hole wall is uneven (high roughness). Specifically, the protrusion 101 can reach a size of 0.2 micrometers on the wall of the 2-micrometers seed hole 10. The subsequent etching and hole enlargement processes still could not remove the fractured structure and unevenness of the hole wall. In addition to the excessive roughness of the hole wall of the through-hole 10′, it also causes problems such as large variation in hole diameter, poor forming (conical or hourglass shape), and misalignment of the openings on the upper and lower surfaces, which in turn affects the yield of subsequent conductive material plating.

Existing technologies attempt to improve the problems of poor via formation and excessively high hole wall roughness by using different etchant compositions, adjusting etching time, and ultrasonic oscillation, but still cannot improve the yield of TGV. Poor TGV results in the inability to produce vertical conductive interconnects that meet the electrical requirements of the package. Furthermore, the TGV numbers required for glass substrates used in 3D packaging reach tens of thousands or even hundreds of thousands, the current method for verifying the TGV uses electron microscopy to confirm whether the aperture and inner wall of the vias meet the requirements after the etching process. Such method is not only time-consuming, but also lacks precise control over the etching process, failing to meet the cost requirements of mass production. Such problems also exist in other industries that use substrates of other materials. Therefore, the industry urgently needs a manufacturing method that can improve the yield of substrates having micro-holes.

### SUMMARY OF THE INVENTION

To solve the various problems of existing substrates having micro-holes, the present invention provides a system of manufacturing a substrate having micro-holes, which includes a solution storage tank, a processing chamber, a boost pump and a recycle pump. The solution storage tank is configured to be filled with a processing solution. The processing chamber has a substrate placement area, a pressure increasing area and a pressure reducing area, wherein a substrate having micro-holes can be placed horizontally and fixed in the substrate placement area, the pressure increasing area is located below the substrate placement area, and the pressure reducing area is located above the substrate placement area. The boost pump is connected to the solution storage tank and the pressure increasing area via pipelines. The recycle pump is connected to the solution storage tank and the pressure reducing area via pipelines.

In an embodiment, the system of manufacturing the substrate having micro-holes further includes a suction member, disposed between the recycle pump and the pressure reducing area and respectively connected to the recycle pump, the pressure reducing area and the solution storage tank via pipelines.

In an embodiment, the suction member includes a solution inlet cavity, a mixing chamber, a throat and a flared section, two ends of the solution inlet cavity are a solution inlet and a solution spray port, the mixing chamber has a gas extracting port located at one end thereof, two sides of the throat are respectively connected to the mixing chamber and the flared section, the gas extracting port is connected to the pressure reducing area via pipelines, and the flared section is connected to the solution storage tank via pipelines.

In an embodiment, the recycle pump is a self-priming pump.

In an embodiment, the system of manufacturing the substrate having micro-holes further includes a flow meter, disposed on the pipelines connecting to the recycle pump and the pressure reducing area, for measuring a flow rate of the processing solution passing through the pressure reducing area.

In an embodiment, the system of manufacturing the substrate having micro-holes further includes a differential pressure gauge, connected to the pressure increasing area and the pressure reducing area respectively, for measuring a differential pressure between the pressure increasing area and the pressure reducing area.

To solve the various problems of existing substrates having micro-holes, the present invention provides a method of manufacturing a substrate having micro-holes, which includes: providing a substrate, which has a first surface and a second surface parallel to each other, and micro-holes communicating the first surface and the second surface; placing the substrate horizontally, and the second surface of the glass substrate being flush with a solution level of a processing solution; increasing a pressure of the processing solution below the second surface, and decreasing a pressure above the first surface, wherein the pressure of the processing solution below the second surface is higher than the pressure above the first surface, causing the processing solution to flow through the micro-holes to displace air in the micro-holes and perform a treatment on hole walls of the micro-holes simultaneously; and stopping the treatment when a flow rate of the processing solution passing through the micro-holes reaches a target value.

In an embodiment, an aspect ratio of the thickness of the substrate to the diameter of the micro-holes is greater than 9.

In an embodiment, a differential pressure between the pressure of the processing solution below the second surface and the pressure above the first surface is adjusted to control a rate of the treatment.

In an embodiment, the rate of the treatment increases as the differential pressure increases, and the rate of the treatment decreases as the differential pressure decreases.

In an embodiment, the treatment is etching or electroless plating.

In an embodiment, the method of manufacturing the substrate having micro-holes further includes: monitoring the flow rate of the processing fluid through the substrate.

In an embodiment, a difference between the maximum diameter and the minimum diameter of the micro-holes is not greater than 5% of the maximum diameter of the micro-holes, after the treatment is stopped.

The present invention identifies a blind spot in existing technology for manufacturing micro-holes on substrates. By creating the differential pressure on both sides of a substrate and utilizing the capillary action of the processing solution to displace air from within the micro-holes, the processing solution is driven by the differential pressure to continuously pass through the micro-holes. Under the effect of the flow velocity, the processing solution uniformly performs a treatment on hole walls of the micro-holes (e.g, etching seed holes to form through-holes and/or plating the hole walls), thereby forming the substrate having micro-holes that meet the requirements of various industries. The system designed according to the method of the present invention allows for the adjustment of differential pressure to control a rate of the treatment. By presetting a target flow rate, the processing (e.g, etching and/or plating) time for manufacturing the micro-holes can be precisely controlled, effectively enhancing process efficiency and yield while reducing manufacturing costs. The substrates manufactured according to the method of the present invention exhibit well-formed micro-holes with high consistency and smooth inner walls, significantly improving the yield of the substrate having micro-holes.

### BRIEF DESCRIPTION OF THE DRAWINGS

FIG. 1 is a top view of the poorly formed through-hole and a vertical cross-sectional view of an electron micrograph of the through-holes of the conventional glass substrate,

FIG. 2A is a block diagram schematically illustrating a system of manufacturing a substrate having a micro-hole according to an embodiment of the present invention,

FIG. 2B is a cross-sectional view schematically illustrating the suction member shown in FIG. 2A,

FIG. 3A is across-sectional view schematically illustrating a seed hole of a glass substrate of an embodiment of the present invention,

FIG. 3B and FIG. 3C are processing diagrams schematically illustrating the process of forming the through-holes of the glass substrate of an embodiment of the present invention,

FIG. 3D is a cross-sectional view schematically illustrating the through-hole of the glass substrate of an embodiment of the present invention,

FIG. 4A and FIG. 4B are processing diagrams schematically illustrating the process of plating the through-holes of the glass substrate of an embodiment of the present invention,

FIG. 4C is a cross-sectional view schematically illustrating a conductive through-hole of the glass substrate of an embodiment of the present invention.

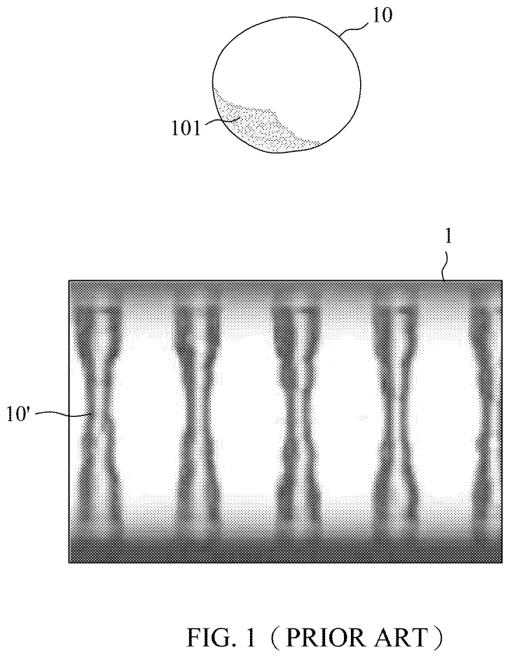

### DETAILED DESCRIPTION OF THE PREFERRED EMBODIMENT

The technical features and other advantages of the present application will become more readily apparent to those ordinarily skilled in the art, by referring to the following detailed description of embodiments of the present application in conjunction with the accompanying drawing. In order to further clarify the technical means adopted in the present application and the effects thereof, the figures schematically illustrate the relative relationship between the main elements, but is not based on the actual size; therefore, thickness, size, shape, arrangement and configuration of the main elements in the figure are only for reference, not intended to limit the scope of the present application.

The problem with existing technology of manufacturing micro-holes (such as through-glass vias, TGV) in the substrate is that it overlooks the presence of air within the laser-formed seed holes. When the substrate is immersed in the processing solution, this air transforms into bubbles during the process, creating liquid-bubble-liquid interfaces within the micro-holes or vias. The pressure within these bubbles impedes the flow of the processing solution, which severely affects uniformity of the treatment that leads to issues such as numerous protrusions on the hole walls of the micro-holes, surface roughness, and significant variations in hole diameter. To overcome the bubbles within the micro-holes, the required pressure P must exceed the surface tension of the liquid, as expressed in the following formula.

$$P > \frac{2 Υ}{r}$$

wherein γ is the surface tension of the liquid, and r is the diameter of the seed hole. Taking the surface tension of water at 25° C. (7.2×10⁻² N/m) and a seed hole diameter of 2 micrometers (μ) as an example:

P>2×7.210-2 N/m/1×10−6 m=14.4×104 N/m2=1.44×105 Pa (1 Kg/cm2=98066.5 Pa)

Conventional ultrasonic vibration or jet pressure generated by nozzles fails to reach the pressure value P required by the aforesaid formula for the micro-holes. As a result, the bubbles remain trapped within the micro-holes, preventing the etchant from uniformly treating the hole walls. This leads to a production yield in the substrate having micro-holes that cannot meet the requirements of industries.

Capillary action results from a combination of the adhesion between a liquid and a solid object and the surface tension generated by the cohesive forces between liquid molecules. Capillary action allows the liquid overcome gravity and rise along a narrow tube or slit. The formula for the rise height h of a liquid in a capillary is as follows:

$$h = \frac{2 γ cos θ}{pgr}$$

wherein γ represents the surface tension coefficient, θ represents the contact angle, ρ represents the density of the liquid, g represents the acceleration due to gravity, and r represents the radius of the capillary. If the contact angle θ between the glass and the liquid is close to 0 degree, the cos θ value approaches 1, the pore size is 2 μm, and the capillary action can push the liquid up to a height of 0.734 meters, which is far greater than the thickness of the glass substrate (about 300 μm to 1000 μm).

The present invention creates a differential pressure on both sides of a substrate and utilizes the capillary action of a processing solution (e.g, etching solution/electroless plating solution) to displace air in the micro-holes of the substrate. Consequently, the processing solution can continuously pass through the micro-holes driven by the differential pressure. Under the effect of the flow velocity, the processing solution uniformly treats the holes walls of the micro-holes, thereby forming the micro-holes of the substrate that meet the requirements of industries.

To take a glass substate for packaging as an example, the method of manufacturing a glass substrate having micro-holes of the present invention includes the process of forming the through-holes and the process of plating the through-holes.

The process of forming through-holes includes the following steps: providing a glass substrate for packaging, wherein the glass substrate has a first surface and a second surface parallel to each other; using a laser beam to form a plurality of seed holes which communicate the first surface and the second surface; placing the glass substrate horizontally, and the second surface of the glass substrate is flush with the solution level of the etching solution; increasing the pressure of the etching solution below the second surface of the glass substrate and decreasing the pressure above the first surface, wherein the pressure below the second surface is higher than the pressure above the first surface, causing the etching solution to flow upward within the seed holes to displace air from the seed holes and etch the inner walls of the seed holes to form through-holes simultaneously; and stopping the etching when the flow rate of the etching solution passing through the through-holes reaches a preset value.

The process of plating through-holes includes the following steps: placing the glass substrate having the through-holes horizontally, and the second surface of the glass substrate being flush with a solution level of a electroless plating solution comprising a conductive material; increasing a pressure of the electroless plating solution below the second surface and decreasing a pressure above the first surface, wherein the pressure of the electroless plating solution below the second surface is higher than the pressure above the first surface, causing the electroless plating solution to flow upward to displace air in the through-holes and plate hole walls of the through-holes to form a conductive material layer at the same time; stopping plating when a flow rate of the electroless plating solution passing through the through-holes reaches a target value; and placing the glass substrate plated with the conductive material vertically, removing the conductive material on the first surface and the second surface of the glass substrate with a conductive material removing solution.

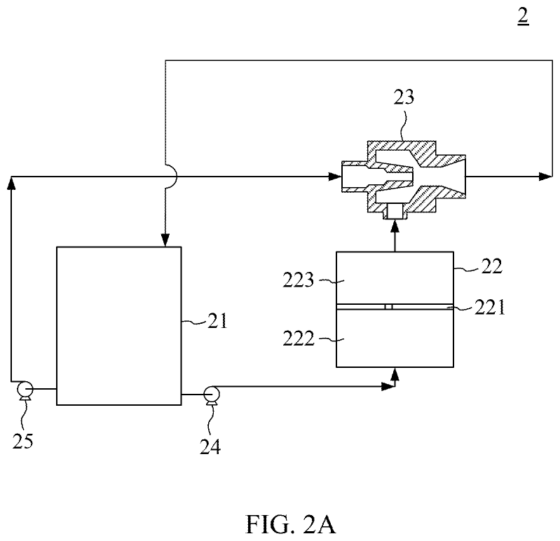

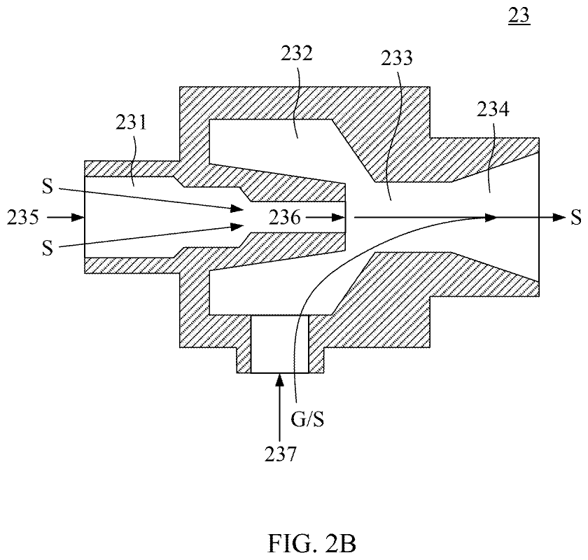

FIG. 2A is a block diagram schematically illustrating a system of manufacturing a glass substrate according to an embodiment of the present invention, FIG. 2B is a cross-sectional view schematically illustrating the suction member shown in FIG. 2A. As shown in FIGS. 2A and 2B, a system of manufacturing a glass substrate 2 includes a solution storage tank 21, a processing chamber 22, a suction member 23, a boost pump 24 and a recycle pump 25. The solution storage tank 21 is used for being filled with a processing solution (etching solution or electroless plating solution). The processing chamber has a substrate placement area 221, a pressure increasing area 222 and a pressure reducing area 223, wherein a glass substrate for packaging can be placed horizontally and fixed in the substrate placement area 221, the pressure increasing area 222 is located below the substrate placement area 221 and is used for being filled with a processing solution, and the pressure reducing area 223 is located above the substrate placement area 221.

The suction member 23 includes a solution inlet cavity 231, a mixing chamber 232, a throat 233 and a flared section 234, two ends of the solution inlet cavity 231 are a solution inlet 235 and a solution spray port 236, the mixing chamber 232 has a gas extracting port 237 located at one end thereof, two sides of the throat 233 are respectively connected to the mixing chamber 232 and the flared section 234, the gas extracting port 237 is connected to the pressure reducing area 233 via pipelines, and the flared section 234 is connected to the solution storage tank 21 via pipelines.

The boost pump 24 is connected to the solution storage tank 21 and the pressure increasing area 222 via pipelines. The recycle pump 25 is connected to the solution storage tank 21 and the pressure reducing area 223 via pipelines. It is worth mentioning that, in other embodiments, a self-priming pump may be selected as the recycle pump 25 and connected to the pressure reducing area 223 via pipelines. In this configuration, the self-priming pump has functions of the suction member 23.

The system of manufacturing the substrate having micro-holes of the present invention is applicable not only to the glass substrates for packaging but also to substrates made of other materials, such as silicon wafers, composite plastics, porous ceramics, battery separator and microporous membrane.

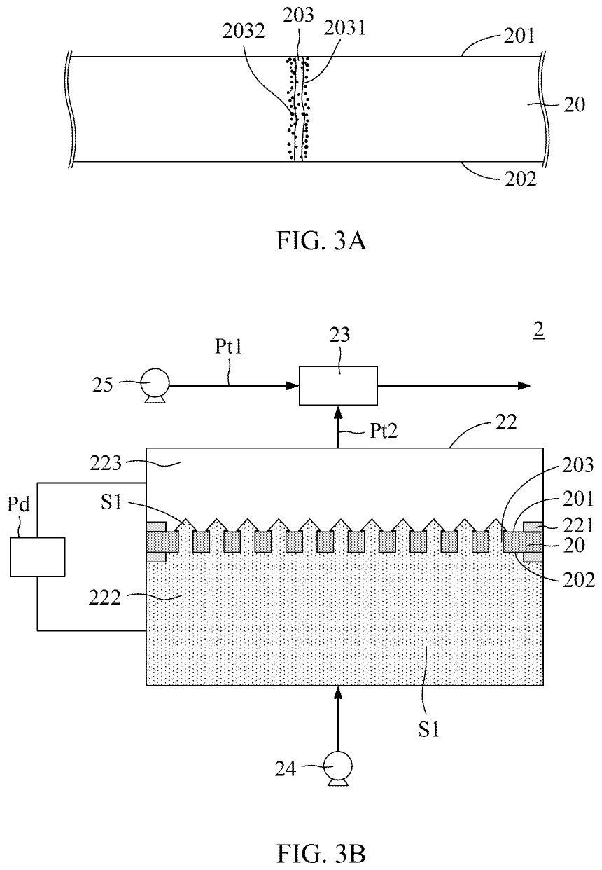

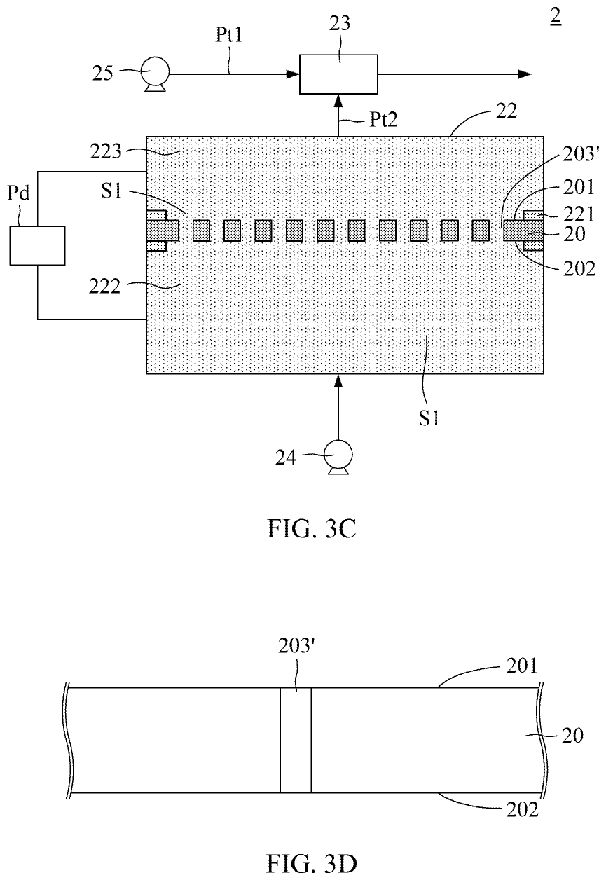

FIG. 3A is a cross-sectional view schematically illustrating the seed hole of the glass substrate of an embodiment of the present invention, FIG. 3B and FIG. 3C are processing diagrams schematically illustrating the process of forming the through-holes of the glass substrate of an embodiment of the present invention, FIG. 3D is a cross-sectional view schematically illustrating the through-hole of the glass substrate of an embodiment of the present invention. As shown in FIG. 2A, FIG. 2B, FIG. 3B and FIG. 3C, in the system of manufacturing the glass substrate 2, a flow meter Pt1 can be disposed on the pipelines that connects to the solution inlet 235 of the suction member 23 and the recycle pump 25, a flow meter Pt2 can be disposed on the pipelines connecting to suction member 23 and the pressure reducing area 223, and a differential pressure gauge Pd can be respectively connected to the pressure increasing area 222 and the pressure reducing area 223 of the processing chamber 22. The solution storage tank 21 and the pressure increasing area 222 of the processing chamber 22 are filled with the processing solution S (etching solution or electroless plating solution). If the concentration or volume of the processing solution S decreases after the process proceeds for a period, additional processing solution S may be supplied into the solution storage tank 21 from other storage tanks (not shown). A filter (not shown) may be disposed between the solution storage tank 21 and the processing chamber 22 to filter out residues or impurities generated during the process. Furthermore, a nozzle array (not shown) may be disposed at the bottom of the pressure increasing area 222 of the processing chamber 22, whereby the processing solution S inputted by the boost pump 24 can be pressurized via the nozzles.

The process of forming the through-holes 203′ in the glass substrate 20 by utilizing the system of manufacturing the glass substrate 2 includes following steps.

As shown in FIG. 3A, a glass substrate 20 for packaging is provided, the glass substrate 20 has parallel and opposite a first surface 201 and a second surface 202. A plurality of seed holes 203, which communicates the first surface and the second surface, is formed in the glass substrate 20 by using the laser light. The hole walls of the seed holes 203 have uneven portion 2031, and cracked structures 2032 (modified part) are formed around the hole walls of the seed holes 203. A shape of the glass substrate 20 is, but not limited to, square of 30 cm×30 cm, a thickness thereof is ranges from 0.5 mm to 1.5 mm. The emission source, frequencies and intensities of the laser light can be selected from those are disclosed in existing technology. A diameter of the seed holes 203 is, but not limited to, 1 μm to 3 μm (e.g. 2 μm). A number of the seed holes 203 ranges from 10000 to 100000.

The solution storage tank 21 is filled with the etching solution S1, the composition and proportion of the etching solution S1 can be selected from that are disclosed in the existing technology, for example, but not limited to hydrogen fluoride (HF) solution.

The glass substrate 20 having the seed holes 203 formed therein is horizontally placed on the substrate placement area 221 of the processing chamber 22, and the boost pump 24 inputs the etching solution S1 to the pressure increasing area 222, till a solution level of the etching solution S1 is flush with the second surface 202 of the glass substrate 20. The term “horizontally placed” in the present invention refers to the first surface 201 and the second surface 202 of the glass substrate 20 are parallel to the solution level of the etching solution S1.

A pressure of the pressure increasing area 222 is set at P1, a pressure of the pressure reducing area 223 is set at P2, and the pressure P1 of the pressure increasing area 222 is higher than the pressure P2 of the pressure reducing area 223 (i.e. a differential pressure between the second surface 202 and the first surface 201 of the glass substrate 20 is P1-P2). The pressure of the etching solution S1 in the pressure increasing area 222 of the processing chamber 22 is boosted to P1 by the boost pump 24, and the recycle pump 25 delivers the etching solution S1 to the solution inlet 231 of the suction member 23. Since a cross section, perpendicular to a flow direction of the etching solution S1, of the solution inlet cavity 231 gradually decreases from the solution inlet 235 to the solution spray port 236, a flow rate of the etching solution S1 passing the solution spray port 236 reaches the fastest velocity that causes the pressure in the mixing chamber 232 to drop, air G in the pressure reducing area 223 of the processing chamber 22 flows into the mixing chamber 232 through the gas extracting port 237 (as shown in FIG. 2B), the etching solution S1 flowing into the throat 233 from the solution spray port 236 is mixed with the air G flowing into the mixing chamber 232, and the etching solution S1 mixed with the air G returns to the solution storage tank 21 via the pipelines.

Due to the suction of the suction member 23 and the capillary action of the etching solution S1 contacting the seed holes 203, the etching solution S1 flows upward to displace air in the seed holes 203 (as shown in FIG. 3B), the air G in the pressure reducing area 223 is gradually emptied by the suction member 23 (as shown in FIG. 2B), the etching solution S1 passed through the seed holes 203 gradually fills the pressure reducing area 223 (as shown in FIG. 3C), and the pressure of the etching solution S1 in the pressure reducing area 223 drops to P2. Under action of the differential pressure between the pressure increasing area 222 and the pressure reducing area 223, the etching solution S1 passes through the seed holes 203 at the designed flow velocity to perform the etching reaction at the same time. The etching solution S1 etches the uneven portion 2031 and the cracked structures 2032 on the hole wall of the seed holes 203 and gradually enlarge the diameter of the seed holes 203 to form through-holes 203′. The etching solution S1 in the pressure reducing area 223 passes through the gas extracting port 237, then flows into the mixing chamber 232, and is mixed with the etching solution S1 flowing into the throat 233 from the solution spray port 236. The mixed etching solution S₁ from the mixing chamber 232 passes through the flared section 234 and then returns to the solution storage tank 21 via the pipelines.

A target diameter of the through-holes 203′ ranges from 60 μm to 100 μm, the flow rate value of the etching solution S1 for etching termination is set according to the number of the through-holes 203′ and the target diameter, and the flow of the etching solution S1 flowing from the pressure reducing area 223 to the suction member 23 is measured. Since the etching solution S1 continuously flows through the through-holes 203′ at the designed flow velocity, the diameter and roughness of the through-holes 203′ reach the target values, after the etching reaction proceeds for a period. When the flow rate of the etching solution S1 gradually increases to the target value, the etching reaction is stopped, and the etched glass substrate 20 is rinsed with water then dried for the subsequent plating process of through-holes. As shown in FIG. 3D, the through-holes 203′ are cylindrical in shape, a height of a protrusion of hole walls of the through-holes 203′ is not greater than 5% (e.g. 1%, 0.5%, 0.1%, 0.01%, 0.001%) of the diameter of the through-holes 203′, “the height of the protrusion” is referred to a difference between the maximum hole diameter and the minimum hole diameter (i.e. roughness).

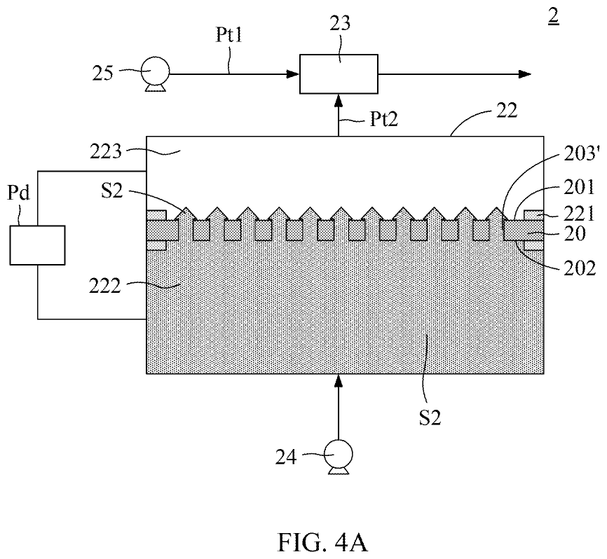

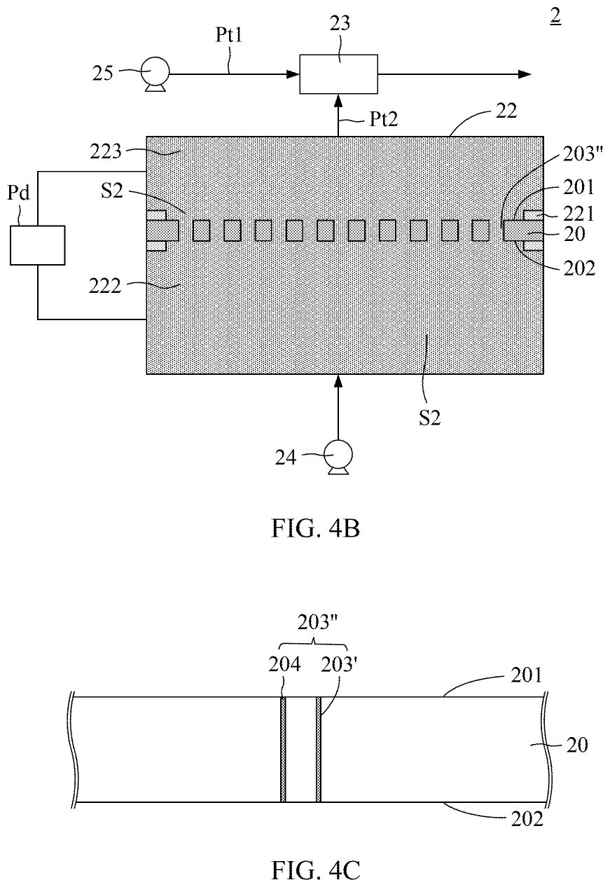

FIG. 4A and FIG. 4B are processing diagrams schematically illustrating the process of plating the through-holes of the glass substrate of an embodiment of the present invention, FIG. 4C is a cross-sectional view schematically illustrating a conductive through-hole of the glass substrate of an embodiment of the present invention. To take the aforesaid glass substrate as an example, as shown in FIG. 2A, FIG. 2B and FIG. 4A, FIG. 4B, the process of plating the through-holes 203′ in the glass substrate 20 by utilizing the system of manufacturing the glass substrate 2 includes following steps.

The solution storage tank 21 is filled with the electroless plating solution S2 (e.g. chemical copper plating solution including copper, and metal compounds for catalysis and modification), the composition and proportion of the etching solution can be selected from those are disclosed in the existing technology.

The glass substrate 20 having the through-holes 203′ formed therein is horizontally placed upon the electroless plating solution S2 in the processing chamber 22, and the boost pump 24 inputs the electroless plating solution S2 to the pressure increasing area 222, till a solution level of the electroless plating solution S2 is flush with the second surface 202 of the glass substrate 20.

A pressure of the pressure increasing area 222 is set at P1′, and a pressure of the pressure reducing area 223 is set at P2′ (i.e. a differential pressure between the second surface 202 and the first surface 201 of the glass substrate 20 is P1′-P2′). The pressure of the electroless plating solution S2 in the pressure increasing area 222 of the processing chamber 22 is boosted to P1′ by the boost pump 24, and the recycle pump 25 delivers the electroless plating solution S2 to the solution inlet 231 of the suction member 23. Since a cross section, perpendicular to a flow direction of the electroless plating solution S2, of the solution inlet cavity 231 gradually decreases from the solution inlet 235 to the solution spray port 236, a flow rate of the electroless plating solution S2 passing the solution spray port 236 reaches the fastest velocity that causes the pressure in the mixing chamber 232 to drop, the air G in the pressure reducing area 223 of the processing chamber 22 flows into the mixing chamber 232 through the gas extracting port 237 (as shown in FIG. 2B), the electroless plating solution S2 flowing into the throat 233 from the solution spray port 236 is mixed with the air G flowing into the mixing chamber 232, and the electroless plating solution S2 mixed with the air G returns to the solution storage tank 21 via the pipelines.

Due to the suction of the suction member 23 and the capillary action of the electroless plating solution S2 contacting the through-holes 203′, the electroless plating solution S2 flows upward to displace air in the through-holes 203′ (as shown in FIG. 4B), air G in the pressure reducing area 223 is gradually emptied by the suction member 23 (as shown in FIG. 2B), the electroless plating solution S2 passed through the through-holes 203′ gradually fills the pressure reducing area 223 (as shown in FIG. 4B), and the pressure of the electroless plating solution S2 in the pressure reducing area 223 drops to P2. Under action of the differential pressure between the pressure increasing area 222 and the pressure reducing area 223, the electroless plating solution S2 passes through the through-holes 203′ at the designed flow velocity to perform the plating reaction at the same time, to form a conductive material layer on the second surface 202, the hole wall of the through-holes 203′ and the first surface 201. The diameter of the through-holes 203′ gradually decreases to become conductive through-holes 203″. The electroless plating solution S2 in the pressure reducing area 223 passes through the gas extracting port 237, then flows into the mixing chamber 232, and is mixed with the electroless plating solution S2 flowing into the throat 233 from the solution spray port 236. The mixed electroless plating solution S2 from the mixing chamber 232 passes through the flared section 234 and then returns to the solution storage tank 21 via the pipelines.

A target thickness of the conductive material layer of the conductive through-hole 203″ ranges from 10 μm to 30 μm, the flow rate value of the electroless plating solution S2 for plating termination is set according to the number of the through-holes and the target thickness, and the flow of the electroless plating solution S2 flowing from the pressure reducing area 223 to the suction member 23 is measured. Since the electroless plating solution S2 continuously flows through the conductive through-holes 203″ at the designed flow velocity, the thickness and roughness of the conductive material layer reach the target values, after the plating reaction proceeds for a period. When the flow rate of the electroless plating solution S2 gradually decreases to the target value, the plating reaction is stopped, and the plated glass substrate is rinsed with water then dried.

The glass substrate 20 plated with the conductive material is placed in a vertical manner (the first surface 201 and the second surface 202 perpendicular to the horizontal plane), the excess conductive material on the first surface 201 and the second surface 202 are removed with a conductive material removing solution. Since the conductive through-holes 203″ of the glass substrate 20 placed in the vertical manner have air therein, the air can block the conductive material removing solution flow into the conductive through-holes 203″, so that the conductive material layer 204 in the conductive through-holes 203″ can be prevented from corrasion of the conductive material removing solution, for subsequent electroplating, packaging and other processes. As shown in FIG. 4C, the conductive through-holes 203″ includes the through-holes 203′ and the conductive material layer 204 plated on hole wall of the through-holes 203′.

It is worth noting that the present invention can adjust the differential pressure to control the rate of etching and plating the glass substrate; that is, the greater the differential pressure is, the faster the etching/plating rate becomes; the smaller the differential pressure is, the slower the etching/plating rate becomes. In the same etching or plating process, the differential pressure can be adjusted to change the etching or plating rate, to make the formation of the through-holes and the conductive layers more uniform. For example, but not limited to, first etch quickly for a period, then reduce the differential pressure to reduce the etching rate; or first plate slowly for a period, then increase the differential pressure to increase the plating rate. Even if the laser beam forms tapered seed holes with an opening on the first surface 201 larger than that on the second surface 202, the process of the etching solution displaces the air in the holes from bottom to top while performing etching ensures higher uniformity in both the via diameter and the formation of conductive materials. Moreover, by presetting the target flow rate, the process time of etching and plating can be precisely controlled, so that the process efficiency and yield is improved, and the process cost is reduced.

The through-holes of the glass substrate manufactured according to the method of the present invention are well-formed, highly consistent, and have smooth hole wall surfaces. Please refer to FIG. 3D again, the glass substrate 20 includes parallel and opposite the first surface 201 and the second surface 202, and the through-holes 203′ communicating the first surface 201 and the second surface 202, the through-holes are cylindrical in shape, the height of protrusions of hole walls of the through-holes 203′ is not greater than 5% (e.g. 1%, 0.5%, 0.1%, 0.01%, 0.001%) of the diameter of the through-holes 203′, “the height of the protrusion” is referred to a distance from the bottom (a position of the maximum hole diameter) to the top (a position of the minimum hole diameter) of the protrusion (i.e. the difference between the maximum hole diameter and the minimum hole diameter). The glass substrate 20 of this embodiment can be applied to 3D packaging process, the number of the through-holes ranges from 10000 to 100000, the thickness of the glass substrate 20 ranges from 0.5 mm to 1.5 mm, the diameter of the through-holes ranges from 60 μm to 100 μm, a ratio of the thickness of the glass substrate 20 to the diameter of the through-hole 203′ (i.e. aspect ratio) can greater than 9, for example, 10, 12, 15.

According to the method of the present invention, the conductive material in the electroless plating solution is easily and completely plated on the hole wall of the through-holes to form the continuous and dense conductive material layer. Please refer to FIG. 4C again, the glass substrate 20 includes the first surface 201, the second surface 202 and the conductive through-hole 203″, the conductive through-hole 203″ includes the through-hole 203 and the conductive material layer 204 plated on hole wall of the through-holes 203′. The thickness of the conductive material layer 201 ranges from 10 μm to 30 μm. The conductive material layer includes copper; it can be a seed layer for subsequent electroplating to fill copper in the conductive through-holes 203″ to form conductive vertical interconnections, so that greatly improves the yield of subsequent electroplating through-holes to form conductive connections and packaging substrates.

### Embodiment 1: Through-Holes of the Glass Substrate for Packaging

A size of the glass substrate: area 30 cm×30 cm, thickness: 800 μm
The diameter of the seed hole D₀: 2 μm
The number of the seed (through) holes: 10000
The maximum protrusion of the seed hole e₀: not greater than 0.2 μm
The etching solution: HF solution (20 v/v %)
The target diameter of the through-hole Dₜ: 80 μm
An average of protrusions of the through-holes et: 2 nanometers
The differential pressure (set) ΔP (=P1-P2): 2 Kg/cm²=2×98066.5 Pa
The flow rates at the start of etching and the flow rate that the target diameter is reached with the differential pressure meter are calculated according to Darcy-Weisbach formula:

$$Δ P = f ( \frac{L}{d} ) ( \frac{{pV}^{2}}{2} )$$

wherein
ΔP represents a friction pressure loss
f represents the coefficient of friction (Darcy coefficient of friction):

$$\frac{1}{√ f} = 2 log 10 ( \frac{( \frac{e}{D} )}{3.7} )$$

L represents a length of pipeline
D represents an inner diameter of hole
ρ represents a density of fluid
V represents an average fluid velocity.
The start of etching:

ΔP=2×98066.5 Pa

f₀=e₀/D₀=0.1
The length of the seed hole (i.e. the thickness of the glass substrate) L₀=8×10⁻⁴ m
The diameter of the seed hole D₀=2×10⁻⁶ m
The density of the etching solution: ρ=10³ Kg/m³
The velocity V₀ of the etching solution at the start of etching is obtained: V₀=3.13 m/s
The flow rate Q₀ of the etching solution at the start of etching: Q₀=V₀×the area of the seed hole A₀(π×D₀²/4)×the number of the seed holes=5.9×10⁻³ l/min
The end of etching:

ΔP=2×98066.5 Pa

Fₜ=eₜ/Dₜ=9.352×10⁻³
The length of the through-hole (i.e. the thickness of the glass substrate) L₀=8×10⁻⁴ m
The diameter of the through-hole Dₜ=80×10⁻⁶ m
The density of the etching solution: ρ=10³ Kg/m3
The velocity Vₜ of the etching solution at the end of etching is obtained: Vₜ=64.7 m/s
The flow rate Qt of the etching solution at the start of etching: Qₜ=Vₜ×the area of the through-hole Aₜ(π×Dₜ²/4)×the number of the through-holes=19.5 l/min
When the measured flow velocity reaches 64.7 m/s or the flow rate reaches 19.5 l/min from the processing chamber to the suction member, it means that the etching has reached the target diameter and the etching can be terminated.

### Embodiment 2: The Through-Holes of the Glass Substrate for Packaging

The diameter of the seed hole D₀: 2 μm
The number of the seed (through) holes: 100000
The maximum protrusion of the seed hole e0: not greater than 0.2 μm
The etching solution: HF solution (20 v/v %)
The target diameter of the through-hole Dₜ: 80 μm
An average of protrusions of the through-holes eₜ: 2 nanometers
The differential pressure (set) ΔP (=P1−P2): 2 Kg/cm²=2×98066.5 Pa
Except that the number of seed holes (through-holes) is increased from 10,000 to 100,000, other parameters and calculation of Embodiment 2 are the same as those of Embodiment 1.
The flow rate of the etching solution at the start of etching: 59.01 l/min
The flow rate of the etching solution at the end of etching: 195 l/min
When the measured flow rate reaches 195 l/min from the processing chamber to the suction member, it means that the etching has reached the target diameter, and the etching can be terminated.

In summary, the present invention identifies a blind spot in existing technology for manufacturing micro-holes on substrates. By creating the differential pressure on both sides of the substrate and utilizing the capillary action of the processing solution to displace air from within the micro-holes, the processing solution is driven by the differential pressure to continuously pass through the micro-holes. Under the effect of the flow velocity, the processing solution uniformly treats the holes walls of the micro-holes, thereby forming the micro-holes that meet the requirements of industries. The system designed according to the method of the present invention allows for the adjustment of differential pressure to control the rate of the treatment on the substrate. By presetting a target flow rate, the processing time for manufacturing the micro-holes can be precisely controlled, effectively enhancing process efficiency and yield while reducing manufacturing costs. The substrates having micro-holes manufactured according to the method of the present invention exhibit well-formed micro-holes with high consistency and smooth inner walls, significantly improving the yield of the substrates having micro-holes.

The above embodiments are merely illustratively illustrative of the principles of the present invention and its effects, and are not intended to limit the present invention. The above embodiments may be modified, combined and altered by anyone skilled in the art, without departing from the spirit and scope of the invention. Therefore, all equivalent modifications, combinations or alterations made by anyone skilled in the art without departing from the spirit and technical principles disclosed by the present invention shall remain within the following claim of the present invention.

What is claimed is:

1. A system of manufacturing a substrate having micro-holes, comprising:
a solution storage tank, configured to be filled with a processing solution;
a processing chamber, having a substrate placement area, a pressure increasing area and a pressure reducing area, wherein a substrate having micro-holes can be placed horizontally and fixed in the substrate placement area, the pressure increasing area is located below the substrate placement area, and the pressure reducing area is located above the substrate placement area;
a boost pump, connected to the solution storage tank and the pressure increasing area via pipelines; and
a recycle pump, connected to the solution storage tank and the pressure reducing area via pipelines.

2. The system of manufacturing the substrate having micro-holes according to claim 1, further comprising: a suction member, disposed between the recycle pump and the pressure reducing area, and respectively connected to the recycle pump, the pressure reducing area and the solution storage tank via pipelines.

3. The system of manufacturing the substrate having micro-holes according to claim 2, wherein the suction member includes a solution inlet cavity, a mixing chamber, a throat and a flared section, two ends of the solution inlet cavity are a solution inlet and a solution spray port, the mixing chamber has a gas extracting port located at one end thereof, two sides of the throat are respectively connected to the mixing chamber and the flared section, the gas extracting port is connected to the pressure reducing area via pipelines, and the flared section is connected to the solution storage tank via pipelines.

4. The system of manufacturing the substrate having micro-holes according to claim 1, wherein the recycle pump is a self-priming pump.

5. The system of manufacturing the substrate having micro-holes according to claim 1, further comprising: a flow meter, disposed on the pipelines connecting to the recycle pump and the pressure reducing area, for measuring a flow rate of the processing solution passing through the pressure reducing area.

6. The system of manufacturing the substrate having micro-holes according to claim 1, further comprising: a differential pressure gauge, connected to the pressure increasing area and the pressure reducing area respectively, for measuring a differential pressure between the pressure increasing area and the pressure reducing area.

7. A method of manufacturing a substrate having micro-holes, comprising:
providing a substrate, which has a first surface and a second surface parallel to each other, and micro-holes communicating the first surface and the second surface;
placing the substrate having micro-holes horizontally, and the second surface of the substrate being flush with a solution level of a processing solution;
increasing a pressure of the processing solution below the second surface, and decreasing a pressure above the first surface, wherein the pressure of the processing solution below the second surface is higher than the pressure above the first surface, causing the processing solution to flow through the micro-holes to displace air in the micro-holes and perform a treatment on hole walls of the micro-holes simultaneously; and
stopping the treatment when a flow rate of the processing solution passing through the micro-holes reaches a target value.

8. The method of manufacturing the substrate having micro-holes according to claim 7, wherein an aspect ratio of the thickness of the substrate to the diameter of the micro-holes is greater than 9.

9. The method of manufacturing the substrate having micro-holes according to claim 7, wherein a differential pressure between the pressure of the processing solution below the second surface and the pressure above the first surface is adjusted to control a rate of the treatment.

10. The method of manufacturing the substrate having micro-holes according to claim 9, wherein the rate of the treatment increases as the differential pressure increases, and the rate of the treatment decreases as the differential pressure decreases.

11. The method of manufacturing the substrate having micro-holes according to claim 7, wherein the treatment is etching or electroless plating.

12. The method of manufacturing the substrate having micro-holes according to claim 7, further comprising: monitoring the flow rate of the processing fluid through the substrate.

13. The method of manufacturing the substrate having micro-holes according to claim 7, wherein a difference between the maximum diameter and the minimum diameter of the micro-holes is not greater than 5% of the maximum diameter of the micro-holes, after the treatment is stopped.
